(19) United States
(12) Patent Application Publication
(10) Pub. No.: US 2016/0164483 A1
(43) Pub. Date: Jun. 9, 2016

(54) COMMON MODE FILTER

(71) Applicant: SAMSUNG ELECTRO-MECHANICS CO., LTD., Suwon-Si (KR)

(72) Inventors: Seung Wook PARK, Suwon-Si (KR); Won Chul SIM, Suwon-Si (KR); Jin Hyuck YANG, Suwon-Si (KR)

(21) Appl. No.: 14/937,086

(22) Filed: Nov. 10, 2015

(30) Foreign Application Priority Data
Dec. 3, 2014 (KR) 10-2014-0172080

(51) Int. Cl. H03H 7/01; H01F 41/04; H03H 3/00; H01F 27/28

(52) U.S. Cl. CPC H03H 7/0138; H01F 27/2804; H01F 41/041; H03H 3/00; H01F 2027/2809

(57) ABSTRACT

A common mode filter includes external electrodes formed by printing and curing a conductive paste. The external electrodes of a multilayer structure having a lower electrode layer are formed by curing the conductive paste and an upper electrode layer formed of a solder.

### CROSS-REFERENCE TO RELATED APPLICATION

This application claims the priority and benefit of Korean Patent Application No. 10-2014-0172080 filed on Dec. 3, 2014, with the Korean Intellectual Property Office, the disclosure of which is incorporated in its entirety herein by reference.

### BACKGROUND

The present disclosure relates to a common mode filter and a method of manufacturing the same.

In accordance with the continuing development of technology, electronic devices such as portable telephones, home appliances, personal computers (PCs), personal digital assistants (PDAs), liquid crystal displays (LCDs), and the like, have changed operating on an analog basis to utilizing a digital scheme, while the speeds of electronic devices has increased due to increases in amounts of data to be processed. Therefore, universal serial bus (USB) 2.0, USB 3.0, and high-definition multimedia interface (HDMI) standards have been widely used in high speed signal transmission interfaces and have been used in a range of digital devices such as personal computers and digital high-definition televisions.

Such interfaces use a differential signal system that transmits differential signals (differential mode signals) using a pair of signal lines, in contrast to a single-end transmitting system that has generally been used in the past. However, electronic devices that are digitized and have increased speeds are sensitive to external stimuli. That is, in a case in which a small abnormal voltage and high frequency noise are introduced to an internal circuit of the electronic device from the outside, a circuit may be damaged or a signal may be distorted.

Here, lightning strikes, electrostatic discharge from the human body, a switching voltage generated within the circuit, power noise included in a power supply voltage, an unnecessary electromagnetic signal, electromagnetic noise, or the like may cause abnormal voltages and noise, generate damage in the circuits of electronic devices and cause signal distortions.

In order to prevent damage to the circuits of electronic devices or to prevent the occurrence of distortion of signals, a filter should be installed to prevent abnormal voltages and high frequency noise from being introduced into the circuit.

Generally, a common mode filter has been used for high speed differential signal lines, or the like, to remove common mode noise therefrom. Common mode noise is referred to as noise generated in differential signal lines, and common mode filters remove noise that may not be removed by an existing electromagnetic interference (EMI) filters. Common mode filters contribute to improvements in the EMI characteristics of home appliances, or the like, or improvement in the antenna characteristics of cellular phones, or the like.

The common mode filter may generally include a magnetic substrate, an insulating layer formed on the magnetic substrate and including a coil conductor layer therein, external electrodes electrically connected to the coil conductor layer, and the like. Here, since the external electrodes are formed by a thin film forming process or a plating process, the external electrodes are formed through several complex processes such as a sputtering process for forming a seed layer, a dry film exposing and developing process, a plating and dry film delaminating process, a seed layer etching process, and the like. Therefore, improvements in terms of production time and costs have been demanded.

### SUMMARY

An aspect of the present disclosure may provide a common mode filter including external electrodes formed by curing a conductive paste to reduce production costs and time consumed in forming the external electrodes of the common mode filter, and a method of manufacturing the same.

According to an aspect of the present disclosure, a common mode filter may include: a body including a magnetic substrate, an insulating layer disposed on the magnetic substrate, and coil electrodes provided in the insulating layer. A plurality of external electrodes are electrically connected to the coil electrodes, wherein the external electrodes may be provided by curing a conductive paste.

According to another aspect of the present disclosure, a common mode filter may include: a body including a magnetic substrate, an insulating layer disposed on the magnetic substrate, and coil electrodes provided in the insulating layer. A plurality of external electrodes electrically connected to the coil electrodes, wherein each of the external electrodes may include a lower electrode layer formed by curing a conductive paste and an upper electrode layer formed of a solder.

According to another aspect of the present disclosure, a method of manufacturing a common mode filter may include: forming a body including a magnetic substrate, an insulating layer formed on the magnetic substrate, and coil electrodes formed in the insulating layer. External electrodes are formed by printing a conductive paste on one surface of the body using a metal mask and curing the printed conductive paste.

According to another aspect of the present disclosure, a method of manufacturing a common mode filter may include: forming a body including a magnetic substrate, an insulating layer formed on the magnetic substrate, and coil electrodes formed in the insulating layer; and forming external electrodes.

The forming of the external electrodes include: forming a lower electrode layer by printing a conductive paste on one surface of the body using a metal mask and curing the printed conductive paste. An upper electrode layer is formed by printing a solder on the cured conductive paste and reflowing the solder.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a perspective view of a common mode filter according to an exemplary embodiment in the present disclosure;

FIG. 2 is a perspective view of a common mode filter according to another exemplary embodiment in the present disclosure;

FIG. 3A is a cross-sectional view illustrating an operation of forming a body in a process of manufacturing a common mode filter according to an exemplary embodiment in the present disclosure;

FIG. 3B is a cross-sectional view illustrating an operation of printing a conductive paste using a mask in the process of manufacturing a common mode filter according to the exemplary embodiment;

FIG. 3C is a cross-sectional view illustrating an operation of forming external electrodes by curing the conductive paste in the process of manufacturing a common mode filter according to the exemplary embodiment;

FIG. 4A is a cross-sectional view illustrating an operation of forming a body in a process of manufacturing a common mode filter according to another exemplary embodiment in the present disclosure;

FIG. 4B is a cross-sectional view illustrating an operation of printing a conductive paste using a mask in the process of manufacturing a common mode filter according to the exemplary embodiment;

FIG. 4C is a cross-sectional view illustrating an operation of curing the conductive paste in the process of manufacturing a common mode filter according to the exemplary embodiment;

FIG. 4D is a cross-sectional view illustrating an operation of forming a solder using a mask in the process of manufacturing a common mode filter according to the exemplary embodiment;

FIG. 4E is a cross-sectional view illustrating an operation of reflowing the solder in the process of manufacturing a common mode filter according to the exemplary embodiment;

FIG. 5 is a cross-sectional view of a common mode filter according to an exemplary embodiment in the present disclosure; and

FIG. 6 is a cross-sectional view of a common mode filter according to another exemplary embodiment in the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

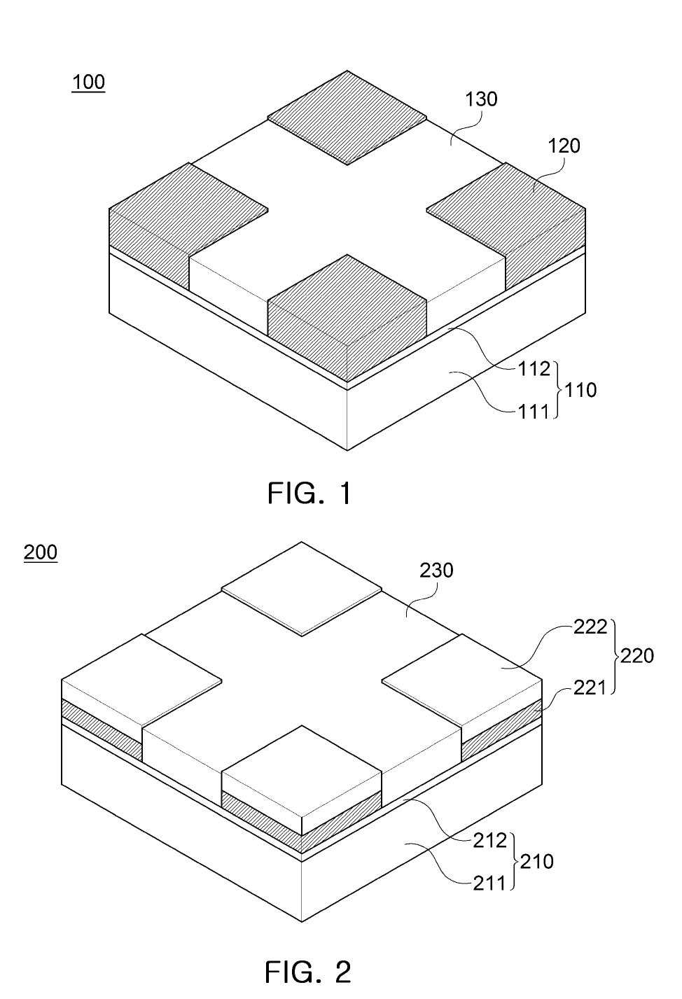

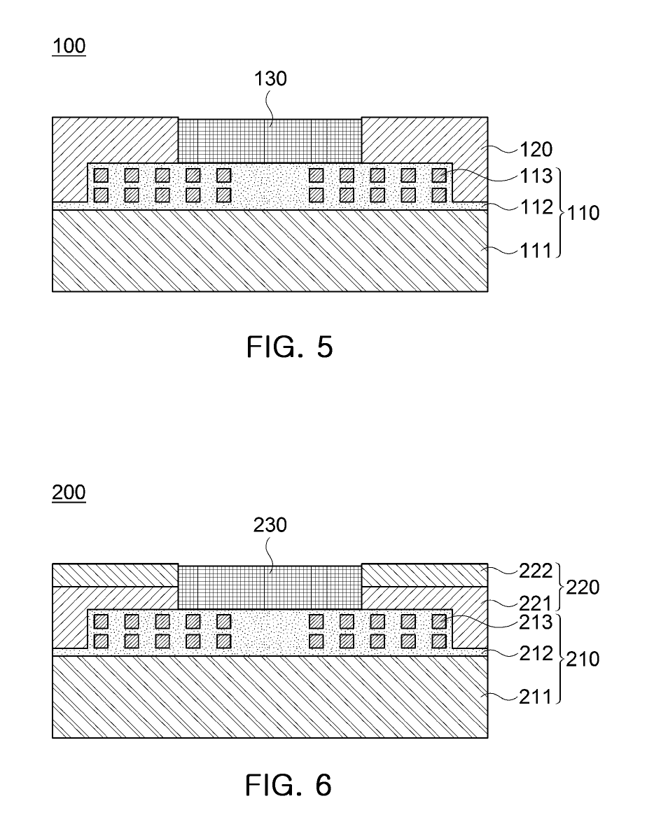

FIG. 1 is a perspective view of a common mode filter according to an exemplary embodiment in the present disclosure and FIG. 5 is a cross-sectional view of the common mode filter according to an exemplary embodiment in the present disclosure.

Referring to FIGS. 1 and 5, a common mode filter 100 according to an exemplary embodiment in the present disclosure may include a body 110 including a magnetic substrate 111, an insulating layer 112 formed on the magnetic substrate, and coil electrodes 113 formed in the insulating layer 112, a plurality of external electrodes 120 formed to be electrically connected to the coil electrodes 113, and a magnetic layer 130. The external electrodes 120 may be formed by curing a conductive paste.

The magnetic substrate 111 may be a base substrate of a finished common mode filter. Since the magnetic substrate 111 is formed of a magnetic material to form a magnetic loop, a material having high permeability, a high quality factor, and high impedance at high frequencies may be used as the material of the magnetic substrate 111.

Specifically, the magnetic substrate may be a ferrite substrate, and may include aluminum oxide (Al₂O₃), aluminum nitride (AlN), glass, quartz, or the like.

The insulating layer 112 may include at least one selected from the group consisting of epoxy, polyimide, polyamide, and mixtures thereof, but is not limited thereto.

The coil electrodes 113 may be formed in the insulating layer and may be formed of a metallic material having high electrical conductivity.

The external electrodes 120, formed by curing the conductive paste, may be electrically connected to the coil electrodes 113, and may form an electrical connection with the substrate or external electronic components.

After the external electrodes 120 are formed, the magnetic layer 130 may be formed by using a composite of a magnetic material and a resin, and electroless plating layers or electroplating layers may be further formed on external surfaces of the external electrodes 120 in order to prevent oxidation and improve reliability, whereby electrical conductivity of the external electrodes 120 may also be improved.

The magnetic layer 130 may be formed of a composite of a ferrite and a polymer resin and may be formed to be provided between the external electrodes 120 on the insulating layer.

The common mode filter 100 according to the present exemplary embodiment may include the plurality of external electrodes 120 formed by curing the conductive paste. Since there is no need to perform several complex processes such as a sputtering process for forming a seed layer, a dry film exposing and developing process, a plating and dry film delaminating process, a seed layer etching process, and the like, according to the related art, the production time and costs of the common mode filter 100 may be reduced.

FIG. 2 is a perspective view of a common mode filter according to another exemplary embodiment in the present disclosure and FIG. 6 is a cross-sectional view of the common mode filter according to another exemplary embodiment in the present disclosure.

Referring to FIGS. 2 and 6, a common mode filter 200 according to this exemplary embodiment may include a body 210 including a magnetic substrate 211, an insulating layer 211 formed on the magnetic substrate 211, and coil electrodes 213 formed in the insulating layer, a plurality of external electrodes 220 formed to be electrically connected to the coil electrodes 213, and a magnetic layer 230. The external electrodes may include a lower electrode layer 221 which is formed by curing a conductive paste and an upper electrode layer 222 formed of a solder.

The magnetic substrate 211 may be a base substrate of a finished common mode filter. Since the magnetic substrate 211 is formed of a magnetic material to form a magnetic loop, a material having high permeability, a high quality factor, and high impedance at high frequencies may be used as the material of the magnetic substrate 211.

Specifically, the magnetic substrate 211 may be a ferrite substrate, and may include aluminum oxide (Al₂O₃), aluminum nitride (AlN), glass, quartz, or the like.

The insulating layer 212 may include at least one selected from the group consisting of epoxy, polyimide, polyamide and mixtures thereof, but is not limited thereto.

The coil electrode 213 may be formed in the insulating layer and may be formed of a metallic material having high electrical conductivity.

The external electrodes 220 may have a multilayer structure including the lower electrode layer 221 formed by curing the conductive paste and the upper electrode layer 222 formed of the solder, and electrical conductivity of the external electrodes 220 may be improved by the upper electrode layer 222 including the solder having relatively high electrical conductivity.

After the external electrodes 220 are formed, a process of forming the magnetic layer 230 by filling a composite of a magnetic material and a resin may be further performed, and electroless plating layers or electroplating layers may be further formed on external surfaces of the external electrodes 220 in order to prevent oxidation and improve reliability, whereby electrical conductivity of the external electrodes 220 may also be improved.

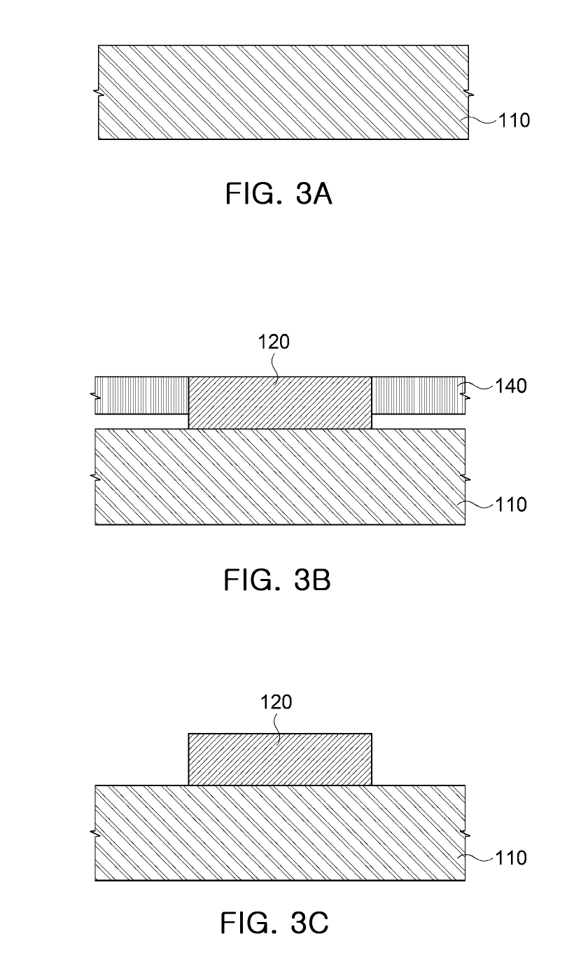

FIG. 3A is a cross-sectional view illustrating an operation of forming a body in a process of manufacturing a common mode filter according to an exemplary embodiment, FIG. 3B is a cross-sectional view illustrating an operation of printing a conductive paste using a mask in the process of manufacturing a common mode filter according to the exemplary embodiment, and FIG. 3C is a cross-sectional view illustrating an operation of forming external electrodes by curing the conductive paste in the process of manufacturing a common mode filter according to the exemplary embodiment.

Referring to FIG. 3A, a body 110 including a magnetic substrate, an insulating layer formed on the magnetic substrate, and coil electrodes formed in the insulating layer may be prepared. Here, a method of forming a body of a typical common mode filter may be used.

Referring to FIG. 3B, a conductive paste maybe printed on a portion on one surface of the body 110 in which an external electrode is to be formed, using a metal mask 140.

The metal mask 140 may be formed by using a laser machining, an etching, an electroforming process, or the like, and a mesh type and a stencil type may be used.

As the conductive paste, a copper (Cu) paste, a silver (Ag) paste, or a copper-silver (Cu—Ag) paste may be used, but the conductive paste is not limited thereto.

Referring to FIG. 3C, the external electrode may be formed by curing the printed conductive paste.

As a method of curing the conductive paste, a UV curing method or a heat curing method may be used, but the method of curing the conductive paste is not limited thereto. For example, a curing temperature, time, and the like may be adjusted depending on a size and a thickness of the external electrode.

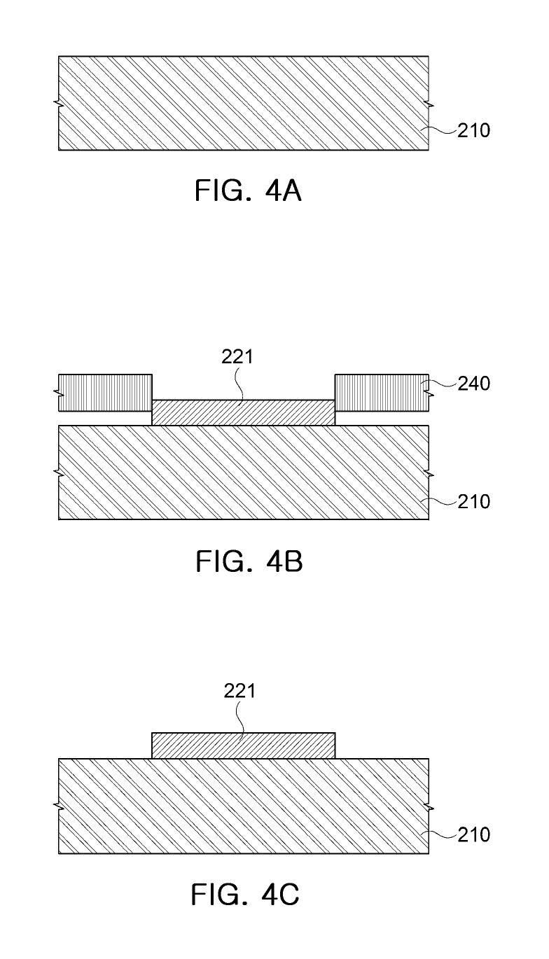

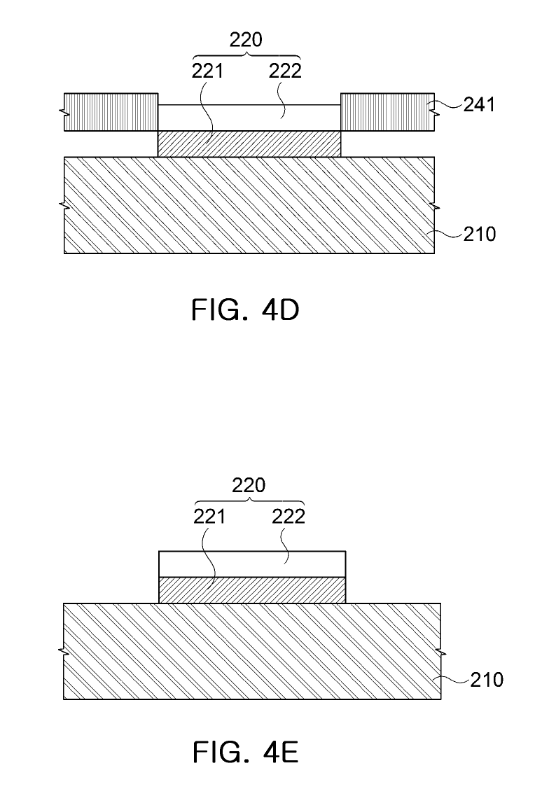

FIG. 4A is a cross-sectional view illustrating an operation of forming a body in a process of manufacturing a common mode filter according to another exemplary embodiment, FIG. 4B is a cross-sectional view illustrating an operation of printing a conductive paste using a mask in the process of manufacturing a common mode filter according to the exemplary embodiment, FIG. 4C is a cross-sectional view illustrating an operation of curing the conductive paste in the process of manufacturing a common mode filter according to the exemplary embodiment, FIG. 4D is a cross-sectional view illustrating an operation of forming a solder using a mask in the process of manufacturing a common mode filter according to the exemplary embodiment, and FIG. 4E is a cross-sectional view illustrating an operation of reflowing the solder according to the exemplary embodiment.

Referring to FIG. 4A, a body 210 including a magnetic substrate, an insulating layer formed on the magnetic substrate, and coil electrodes formed in the insulating layer may be prepared. Here, a method of forming a body of a typical common mode filter may be used.

Referring to FIG. 4B, a conductive paste may be printed on a portion of one surface of the body 210 in which an external electrode is to be formed, using a metal mask 240.

However, since the external electrode of the common mode filter according to the present exemplary embodiment is formed to have a multilayer structure, a level of the printed conductive paste may be adjusted to be low.

The metal mask 240 may be formed using a laser machining process, an etching process, an electroforming process, or the like, and a mesh type and a stencil type may be used.

As the conductive paste, a copper (Cu) paste, a silver (Ag) paste, or a copper-silver (Cu—Ag) paste may be used, but the conductive paste is not limited thereto.

Referring to FIG. 4C, a lower electrode layer 221 of the external electrodes may be formed by curing the printed conductive paste.

As a method of curing the conductive paste, an UV curing method or a heat curing method may be used, but the method of curing the conductive paste is not limited thereto. For example, a curing temperature, time, and the like may be adjusted depending on a size and a thickness of the external electrode.

Referring to FIG. 4D, a solder may be printed on the lower electrode layer 221 using a metal mask 241.

As the solder, a Sn/Ag/Cu (SAC) solder may be used, but the solder is not limited thereto.

Referring to FIG. 4E, an upper electrode layer 222 of the external electrode may be formed by reflowing the printed solder.

The external electrode 220 of the common mode filter 200 according to the present exemplary embodiment may have the multilayer structure including the lower electrode layer 221 formed of the conductive paste and the upper electrode layer 222 formed of the solder, and electrical conductivity of the external electrode 220 may be improved by the upper electrode layer 222 including the solder having relatively high electrical conductivity.

As set forth above, according to exemplary embodiments in the present disclosure, the common mode filter may include the plurality of external electrodes formed by curing the conductive paste. Since there is no need to perform several complex processes such as a sputtering process for forming a seed layer, a dry film exposing and developing process, a plating and dry film delaminating process, a seed layer etching process, and the like as in the method using the plating method or the thin film process according to the related art, the production time and costs of the common mode filter may be reduced.

While exemplary embodiments have been shown and described above, it will be apparent to those skilled in the art that modifications and variations could be made without departing from the scope of the present invention as defined by the appended claims.

What is claimed is:

1. A common mode filter comprising:
a body including a magnetic substrate, an insulating layer disposed on the magnetic substrate, and coil electrodes provided in the insulating layer; and
a plurality of external electrodes electrically connected to the coil electrodes,
wherein the external electrodes are provided by curing a conductive paste.

2. The common mode filter of claim 1, wherein the magnetic substrate is a ferrite substrate.

3. The common mode filter of claim 1, wherein the insulating layer includes at least one selected from the group consisting of epoxy, polyimide, polyamide, and mixtures thereof.

4. The common mode filter of claim 1, wherein the external electrodes include plating layers provided on surfaces thereof.

5. The common mode filter of claim 1, further comprising a magnetic layer formed on the insulating layer.

6. A common mode filter comprising:
a body including a magnetic substrate, an insulating layer disposed on the magnetic substrate, and coil electrodes provided in the insulating layer; and
a plurality of external electrodes electrically connected to the coil electrodes,
wherein each of the external electrodes includes a lower electrode layer provided by curing a conductive paste and an upper electrode layer formed of a solder.

7. The common mode filter of claim 6, wherein the magnetic substrate is a ferrite substrate.

8. The common mode filter of claim 6, wherein the insulating layer includes at least one selected from the group consisting of epoxy, polyimide, polyamide, and mixtures thereof.

9. The common mode filter of claim 6, wherein the external electrodes further include plating layers provided on surfaces thereof.

10. The common mode filter of claim 6, further comprising a magnetic layer formed on the insulating layer.

11. A method of manufacturing a common mode filter, the method comprising:
forming a body including a magnetic substrate, an insulating layer disposed on the magnetic substrate, and coil electrodes provided in the insulating layer;
forming, on the insulating layer, a conductive paste electrically connected to the coil electrodes; and
forming a lower electrode layer by curing the conductive paste.

12. The method of claim 11, further comprising forming a magnetic layer on the insulating layer.

13. The method of claim 11, further comprising forming plating layers on a surface of the lower electrode layer.

14. The method of claim 11, further comprising:
disposing a solder on the lower electrode layer; and
forming an upper electrode layer by reflowing the disposed solder.

15. The method of claim 14, further comprising forming plating layers on a surface of the upper electrode layer.

16. The method of claim 11, wherein the insulating layer includes at least one selected from the group consisting of epoxy, polyimide, polyamide, and mixtures thereof.

17. The method of claim 11, wherein the conductive paste is at least one selected from the group consisting of a copper (Cu) paste, a silver (Ag) paste, and a copper-silver (Cu—Ag) paste.

18. The method of claim 11, wherein the magnetic substrate is a ferrite substrate.
